(19) United States
(12) Patent Application Publication
(10) Pub. No.: US 2017/0316920 A1
(43) Pub. Date: Nov. 2, 2017

(54) APPARATUS AND METHOD FOR TREATING A SUBSTRATE

(71) Applicant: SEMES CO., LTD., Cheonan-si (KR)

(72) Inventors: Harutyun MELIKYAN, Cheonan-si (KR); Junghwan LEE, Ansan-si (KR); Jong Hwan AN, Yongin-si (KR); Shin-Woo NAM, Yongin-si (KR)

(73) Assignee: SEMES CO., LTD., Cheonan-si (KR)

(21) Appl. No.: 15/443,212

(22) Filed: Feb. 27, 2017

(30) Foreign Application Priority Data
Apr. 29, 2016 (KR) 10-2016-0052928

(51) Int. Cl. H01J 37/32; H01L 21/67

(52) U.S. Cl. CPC H01J 37/3211; H01L 21/67069; H01J 37/3244; H01J 2237/334

(57) ABSTRACT

An antenna and a substrate treating process utilizing the same are provided. The antenna may extend along an imaginary baseline having predetermined curvature and comprise a section where the distance between the baseline and intersection point between the antenna and a vertical line perpendicular to the baseline changes depending on a position on the baseline.

### CROSS-REFERENCE TO RELATED APPLICATIONS

A claim for priority under 35 U.S.C. §119 is made to Korean Patent Application No. 10-2016-0052928 filed Apr. 29, 2016, in the Korean Intellectual Property Office, the entire contents of which are hereby incorporated by reference.

### BACKGROUND OF THE INVENTION

The present disclosure relates to an antenna and apparatus for treating substrate utilizing the same.

Plasma is widely used in a semiconductor process. For example, an etching process may remove a thin film on a substrate by generating plasma on the substrate and then accelerating an ion within the plasma to the substrate. Thus, plasma affects producing a product in the semiconductor process.

To generate plasma, a chamber may be provided with high frequency power and make a gas within the chamber into a plasma state. An ICP (Inductively Coupled Plasma) is one of a method for generating plasma by supplying high frequency power to a chamber. This ICP method forms inductive electromagnetic field within the chamber by supplying a RF signal to an antenna installed in the chamber, and ignites and maintains plasma using inductive electromagnetic field.

Recently, it has been required to equally treat entire wafer since size of a wafer used in semiconductor process is getting bigger and bigger. Thus, a new type of antenna is needed to enhance productivity of a substrate treating process by forming an electromagnetic field equally on the substrate.

### SUMMARY OF THE INVENTION

The present disclosure provides an antenna which may enhance productivity in a substrate treating process employing inductively coupled plasma method and a substrate treating apparatus utilizing the same.

Embodiments of the inventive concept provide an antenna which may extend along an imaginary baseline having predetermined curvature. The antenna may comprise a section where the distance between the baseline and an intersection point between the antenna and a vertical line perpendicular to the baseline changes depending on a position on the baseline.

In example embodiment, the baseline may comprise a straight line where a curvature is 0 or a curve where a curvature is a positive number.

In example embodiment, the baseline may comprise a section where a curvature changes depending on a position on the baseline.

In example embodiment, a position on the baseline and the distance may be independent variable and dependent variable of a periodic function, respectively.

In example embodiment, a position on the baseline and the distance may be independent variable and dependent variable of a sine function, respectively.

In example embodiment, a position on the baseline and the distance may be independent variable and dependent variable of a polynomial function or a linear function in some sections of the antenna, respectively.

In example embodiment, a maximum value of the distance may be the same or smaller than a minimum value of a length between points on the baseline having maximum distance.

In example embodiment, the antenna may further comprise a section where the distance is constant.

In example embodiment, the antenna may alternatively comprise a section where the distance changes and a section where the distance is constant.

In example embodiment, a length of the section where the distance changes may be longer or the same with the section where the distance is constant.

In example embodiment, the antenna may comprise n number of winding wires extending over 360°/n of azimuth; n may be a natural number.

In example embodiment, n may be an even number and the n number of winding wires may be arranged for the antenna to be symmetrical.

In example embodiment, the antenna may comprise M number of winding wires extending over 360°×N of azimuth; N may be a real number bigger than 0, M may be a natural number.

In example embodiment, M may be an even number and the M number of winding wires may be arranged for the antenna to be symmetrical.

In other embodiments of the inventive concept, a substrate treating apparatus may comprise: a chamber for providing a substrate treating space therein; a substrate supporting assembly for supporting the substrate and placed within the chamber; a gas supply unit for supplying a gas within the chamber; and a plasma generating unit for making the gas into a plasma state, wherein the plasma generating unit may comprise: a RF power for supplying RF signal; and

an antenna generating plasma from a gas supplied in the chamber by supplied with the RF signal, extended along an imaginary baseline having predetermined curvature, and comprising a section where the distance between the baseline point and the antenna point on a vertical line which is perpendicular to the base line changes depending on a position on the baseline.

In example embodiment, the baseline may comprise a straight line where a curvature is 0 or a curve where a curvature is positive number.

In example embodiment, the baseline may comprise a section where a curvature changes depending on a position on the baseline.

In example embodiment, a position on the baseline and the distance may be independent variable and dependent variable of a periodic function, respectively.

In example embodiment, a position on the baseline and the distance may be independent variable and dependent variable of a sine function, respectively.

In example embodiment, a position on the baseline and the distance may be independent variable and dependent variable of a polynomial function or a linear function in some sections of the antenna, respectively.

In example embodiment, a maximum value of the distance may be the same or smaller than a minimum value of a length between points on the baseline having a distance relevant to the maximum value.

In example embodiment, the antenna may further comprise a section here the distance is constant.

In example embodiment, the antenna may alternatively comprise a section where the distance changes and a section where the distance is constant.

In example embodiment, a length of the section where the distance changes may be longer or the same with the section where the distance is constant.

In example embodiment, the antenna may comprise n number of winding wires extending over 360°/n of azimuth; n may be a natural number.

In example embodiment, the antenna may comprise M number of winding wires extending over 360°×N of azimuth; N may be a real number bigger than 0, M may be a natural number.

According to an example embodiment, a time for igniting and ionizing plasma may be reduced as dispersion of an electromagnetic field formed by an antenna is improved.

According to an example embodiment, a reflection power which returns to RF power by reflected from an antenna when igniting plasma may be reduced.

According to an example embodiment, substrate contamination and product damage by particle may be reduced since spike which generate when igniting plasma may be reduced.

### BRIEF DESCRIPTION OF THE DRAWINGS

FIG. 1 is an exemplary drawing of a substrate treating apparatus according to an example embodiment of the present inventive concepts.

FIG. 2 is an exemplary plan view of an antenna according to an example embodiment of the present inventive concepts.

FIG. 3 is an enlarged view of part A of FIG. 2.

FIG. 4 is an exemplary plan view of an antenna according to another example embodiment.

FIG. 5 is an exemplary plan view of an antenna according to another example embodiment.

FIG. 6 is an enlarged view of part B of FIG. 5.

FIG. 7 is an exemplary plan view of an antenna according to another example embodiment.

FIG. 8 is an enlarged view of part C of FIG. 7.

FIGS. 9 and 10 are exemplary plan views of an antenna according to another example embodiment.

### DETAILED DESCRIPTION

Various example embodiments will be described more fully hereinafter with reference to the accompanying drawings, in which some example embodiments are shown. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims.

Unless otherwise defined, all terms (including technical and scientific terms) used herein have the same meaning as commonly understood by one of ordinary skill in the art to which inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

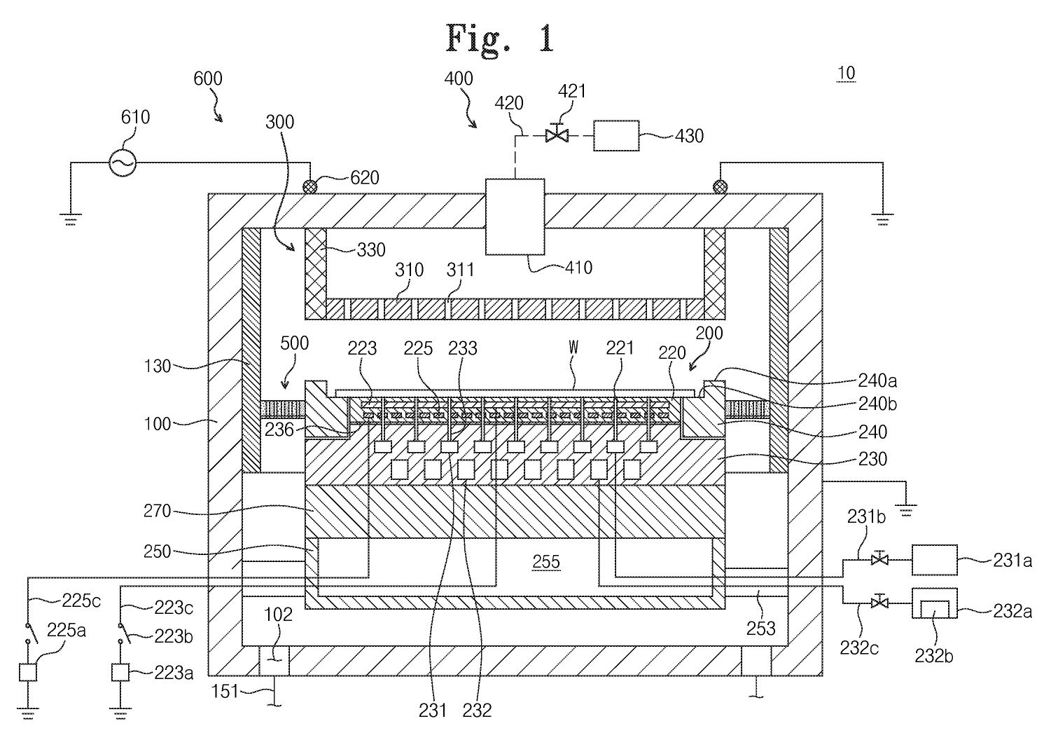

FIG. 1 is an exemplary drawing of a substrate treating apparatus 10 according to an example embodiment of the present inventive concepts.

Referring to FIG. 1, the substrate treating apparatus 10 treats the substrate W using plasma. For example, the substrate treating apparatus 10 may perform an etching process with respect to the substrate W. The substrate treating apparatus 10 may include a chamber 100, a substrate support assembly 200, a shower head 300, a gas supply unit 400m, a baffle unit 500, and a plasma generating unit 600.

The chamber 100 may provide a space for performing a process for treating a substrate therein. The chamber 100 may have treating space therein and may be provided as a sealed form. The chamber 100 may be provided with a metal material. The chamber 100 may be provided with an aluminum material. The chamber 100 may be grounded. An exhaust hole 102 may be formed on a bottom surface of the chamber 100. The exhaust hole 102 may be connected to an exhaust line 151. A reaction by-product generated in a process step and a gas which exists in an internal space of the chamber may be discharged through the exhaust line 151. The internal space of the chamber 100 may be decompressed to a predetermined compression by an exhaust process.

According to an example, a liner 130 may be provided in the chamber 100. The liner 130 may have a cylinder shape where a top end portion and a bottom end portion are opened. The liner 130 may be provided to contact with an inner sidewall of the chamber 100. The liner 130 may protect the inner sidewall of the chamber 100, thereby making it possible to prevent the inner sidewall of the chamber 100 from the arc discharge. Furthermore, the liner 130 may prevent impurities generated during a process for treating a substrate from being deposited on the inner sidewall of the chamber 100. Selectively, the linear 130 may not be provided.

The substrate support assembly 200 may be located in the chamber 100. The substrate support assembly 200 may support the substrate W. The substrate support assembly 200 may include an electrostatic chuck 210 for holding the substrate W using an electrostatic force. On the other hand, the substrate support assembly 200 may support the substrate W in various methods such as a mechanical clamping. The substrate support assembly 200 including the electrostatic chuck 210 may be described as follows.

The substrate support assembly 200 may include an electrostatic chuck 210, a bottom cover 250 and a plate 270. The substrate support assembly 200 may be installed to be apart from the bottom surface of the chamber 100 in the chamber 100.

The electrostatic chuck 210 may include a dielectric plate 220, a body 230, and a focus ring 240. The electrostatic chuck 210 may support the substrate W. The dielectric plate 220 may be located on the electrostatic chuck 210. The dielectric plate 220 may be a dielectric substance having a circular shape. The substrate W may be placed on upper surface of the dielectric plate 220. A radius of the upper surface of the dielectric plate 220 may have a smaller than that of the substrate W. Thereby, a boundary area of the substrate W may be located outside the dielectric plate 220.

The dielectric plate 220 may include a first electrode 223, a heater 225, and a first supply path 221. The first supply path 221 may be provided from an upper side 220 to a bottom surface of the dielectric plate 220. The first supply path 221 may include a plurality of paths which are spaced apart from each other, and be used as a path through which heat transmission media is supplied to a bottom surface of the substrate W.

The first electrode 223 may be electrically connected with a first power 223a. The first power 223a may include a direct current. A switch 223b may be installed between the first electrode 223 and the first power 223a. The first electrode 223 may be electrically connected to the first power 223a in response to activation of the switch 223b. When the switch 223b is turned on, the direct current may be applied to the first electrode 223. An electrostatic force generated by a current applied to the first electrode 223 may operate between the first electrode 223 and the substrate W. The substrate may be held on the dielectric plate 220 by the electrostatic force.

The heater 225 may be located at the bottom of the first electrode 223. The heater 225 may be electrically connected to a second power 225a. The heater 225 may generate heat by resisting a current from the second power 225a. The heat may be transmitted to the substrate W through the dielectric plate 220. The substrate W may maintain predetermined temperature by the heat generated from the heater 225. The heater 225 may include a helical coil.

The body 230 may be located under the dielectric plate 220. A bottom surface of the dielectric plate 220 and a top surface of the body 230 may be adhered by an adhesive 236. The body 230 may be made of aluminum material. The center area of the top surface of the body 230 may be higher than a boundary area. The center area of the top surface of the body 230 may correspond to the bottom surface of the dielectric plate 220 and may be adhered to the bottom surface of the dielectric plate 220. A first circulation path 231, a second circulation path 232 and a second supply path 233 may be formed in the body 230.

The first circulation path 231 may be used as a path which heat transmission media is circulated. The first circulation path 231 may be formed in the body 230 in a helical shape. Or, the first circulation path 231 may include ring-shaped paths having different radius. The paths may be arranged such that centers of the paths have the same height. The first circulation paths 231 may be connected with each other. The first circulation paths 231 may be formed at the same height.

The second circulation path 232 may be used as a path where cooling fluid is circulated. The second circulation path 232 may be formed in the body 230 in a helical shape. Or, the second circulation path 232 may include ring-shaped paths having different radius. The paths may be arranged such that centers of the paths have the same height. The second circulation paths 232 may be connected with each other. The second circulation path 232 may have a cross-sectional area larger than the first circulation path 231. The second circulation path 232 may be formed at the same height. The second circulation path 232 may be located under the first circulation path 231.

The second supply path 233 may extend upward from the first circulation path 231 and may be provided on the body 230. The number of the second supply path 233 may correspond to that of paths of the first supply path 221. The second supply path 233 may connect the first circulation path 231 and the first supply path 221.

The first circulation path 231 may be connected to heat transmission media storage unit 231a via a supply line 231b. The heat transmission media storage unit 231a may store heat transmission media. The heat transmission media may include an inert gas. In an embodiment, the heat transmission media may include a helium gas. The helium gas may be supplied to the first circulation path 231 via the supply line 231b. Moreover, the helium gas may be supplied to the bottom surface of the substrate W through the second supply path 233 and the first supply path 221. The helium gas may be a media through which heat transmitted from plasma to the substrate W is transmitted to the electrostatic chuck 210.

The second circulation path 232 may be connected to a cooling fluid storage unit 232a via a cooling fluid supply line 232c. The cooling fluid storage unit 232a may store cooling fluid. The cooling fluid storage unit 232a may include a cooler 232b. The cooler 232b may lower a temperature of the cooling fluid. On the other hand, the cooler 232b may be installed on the cooling fluid supply line 232c. The cooling fluid supplied to the second circulation path 232 via the cooling fluid supply line 232c may circulate along the second circulation path 232, thereby making it possible to cool the body 230. As cooled, the body 230 may cool both the dielectric plate 220 and the substrate W to allow the substrate W to remain at a predetermined temperature.

The body 230 may include a metal plate. In an embodiment, entire body 230 may be provided with a metal plate.

The focus ring 240 may be arranged in a boundary are of the electrostatic chuck 210. The focus ring 240 may have a ring shape and be arranged along a circumstance of the dielectric plate 220. A top surface of the focus ring 240 may be installed such that an outer top surface 240a is higher than an inner top surface 240b. The inner top surface 240b of the focus ring 240 may be located at the same height as a top surface of the dielectric plate 220. The inner top surface 240b of the focus ring 240 may support a boundary area of the substrate W located outside the dielectric plate 220. The outer top surface 240a of the focus ring 240 may surround the boundary area of the substrate W. The focus ring 240 may control an electromagnetic field so that the density of plasma may be equally dispersed throughout the substrate W. According to this, plasma may equally form throughout the entire area of the substrate W, thereby equally etching each area of the substrate W.

The bottom cover 250 may be located under the substrate support assembly 200. The bottom cover 250 may be installed to be spaced apart from the bottom surface of the chamber 100. The bottom cover 250 may include a space 255 where a top surface is opened. An outer radius of the bottom cover 270 may be equal to an outer radius of the body 230. A left pin module (not shown) for moving the substrate W to be returned from an outside return element to the electrostatic chuck 210 may be located in the inner space 255 of the bottom cover 250. The left pin module (not shown) may be located to be spaced apart from the bottom cover 250. A bottom surface of the bottom cover 250 may be made of a metal material. The inner space 255 of the cover 250 may be provided with air. As the air has lower permittivity than insulation it may lower electromagnetic field within the substrate support assembly 200.

The bottom cover 250 may have a connection element 253. The connection element 253 may connect an outer sidewall of the bottom cover 250 and an inner sidewall of the chamber 100. The connection element 253 may include a plurality of connection elements which are placed i.e. space apart from the outer sidewall of the bottom cover 270. The connection element 253 may support the substrate support assembly 220 in the chamber 100. Further, the connection element 253 may be connected to the inner sidewall of the chamber 100, thereby making it possible for the bottom cover 250 to be electrically grounded. A first power line 223c connected to a first power 223a, a second power line 225c connected to a second power 225a, the heat transmission media supply line 231b connected to the heat transmission media storage unit 231a, and the cooling fluid supply line 232c connected to the cooling fluid storage unit 232a may be extended into the bottom cover 250 through the inner space 255 of the connection element 253.

A plate 270 may be located between the electrostatic chuck 210 and the bottom cover 250. The plate 270 may cover upper surface of the bottom cover 250. A cross-sectional area of the plate 270 may correspond to the body 230. The plate 270 may include an insulator. In an embodiment, the plate 270 may be provided with one or a plurality of numbers. The plate 270 may increase electrical distance between the body 230 and the bottom cover 250.

The shower head 300 may be placed on top side of the substrate support assembly 200 in the chamber 100. The shower head 300 may be opposed to the substrate support assembly 200.

The shower head 300 may include a gas disperse plate 310 and a supporter 330. The gas disperse plate 310 may be placed to be spaced apart from the upper surface of the chamber 100. A regular space may be formed between the gas disperse plate 310 and the upper surface of the chamber 100. The gas disperse plate 310 may be provided with a plate form having constant thickness. A bottom surface of the gas disperse plate 310 may be polarized to prevent are discharge generated by plasma. A cross-section of the gas disperse plate 310 may have the same form and a cross-section area with the substrate support assembly 200. The gas disperse plate 310 may include a plurality of discharge holes 311. The discharge hole 311 may penetrate the gas disperse plate 310 vertically. The gas disperse plate 310 may include metal material.

The supporter 330 may support a lateral end of the gas disperse plate 310. A top end of the supporter 330 may be connected to upper surface of the chamber 100 and a bottom end of the supporter 330 may be connected to the lateral end of the gas disperse plate 310. The supporter 330 may include nonmetal material.

The gas supply unit 400 may provide a process gas into the chamber 100. The gas supply unit 400 may include a gas supply nozzle 410, a gas supply line 420, and a gas storage unit 430. The gas supply nozzle 410 may be installed in a center area of the chamber 100. An injection nozzle may be formed on a bottom surface of the gas supply nozzle 410. The injection nozzle may provide a process gas into the chamber 100. The gas supply line 420 may connect the gas supply nozzle 410 and the gas storage unit 430. The gas supply line 420 may provide a process gas stored in the gas storage unit 430 to the gas supply nozzle 410. A valve 421 may be installed on the gas supply line 420. The valve 421 may turn on or off the gas supply line 420 and adjust the amount of process gas supplied via the gas supply line 420.

The baffle unit 500 may be installed between inner sidewall of the chamber 100 and the substrate support assembly 200. A baffle 510 may be a ring shape. A plurality of penetration holes 511 may be formed in the baffle 510. A process gas provided in the chamber 100 may be exhausted to an exhaust hole 102 through penetration holes 511 of the baffle 510. A flow of the process gas may be controlled depending on shapes of the baffles 510 and penetration holes 511.

The plasma generating unit 600 may make a process gas in the chamber 100 into a plasma state. In an embodiment, the plasma generating unit 600 may be implemented in an ICP-type. In this case, as shown in FIG. 1, the plasma generation unit 600 may include a RF power 610 for supplying high-frequency power and an antenna 620 electrically connected to the RF power and receiving RF signal.

The antenna 620 may be symmetrical to the substrate W. For example, the antenna 620 may be installed in top side of the chamber 100. The antenna 620 may receive RF signal from the RF power 610 and induce time-varying magnetic field to the chamber, thereby the process gas provided in the chamber 100 may be made into a plasma state.

A process for treating a substrate using described substrate treating apparatus may be described as follows.

When the substrate W is placed on the substrate support assembly 200, a direct current may be applied to the first electrode 223 from the first power 223a. An electrostatic force generated by a direct current to the first electrode 223 may operate between the first electrode 223 and the substrate W. The substrate may be held on the electrostatic chuck 210 by the electrostatic force.

When the substrate W is held on the electrostatic chuck 210, a process gas may be provided in the chamber 100 through gas supply nozzle 410. The process gas may be equally dispersed to inner area of the chamber 100 through the discharge hole 311 of the shower head 300. An RF signal generated on the RF power 610 may be applied to the antenna 620 which is a plasma source and thereby an electromagnetic field may be generated in the chamber 100. The electromagnetic field may make a process gas between the substrate support assembly 200 and the shower head 300 into a plasma state. Plasma may be provided to the substrate W and treat the substrate W. plasma may perform etching process.

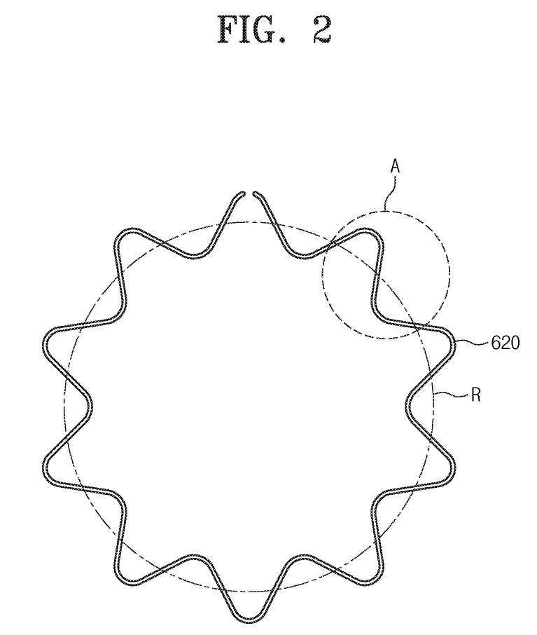

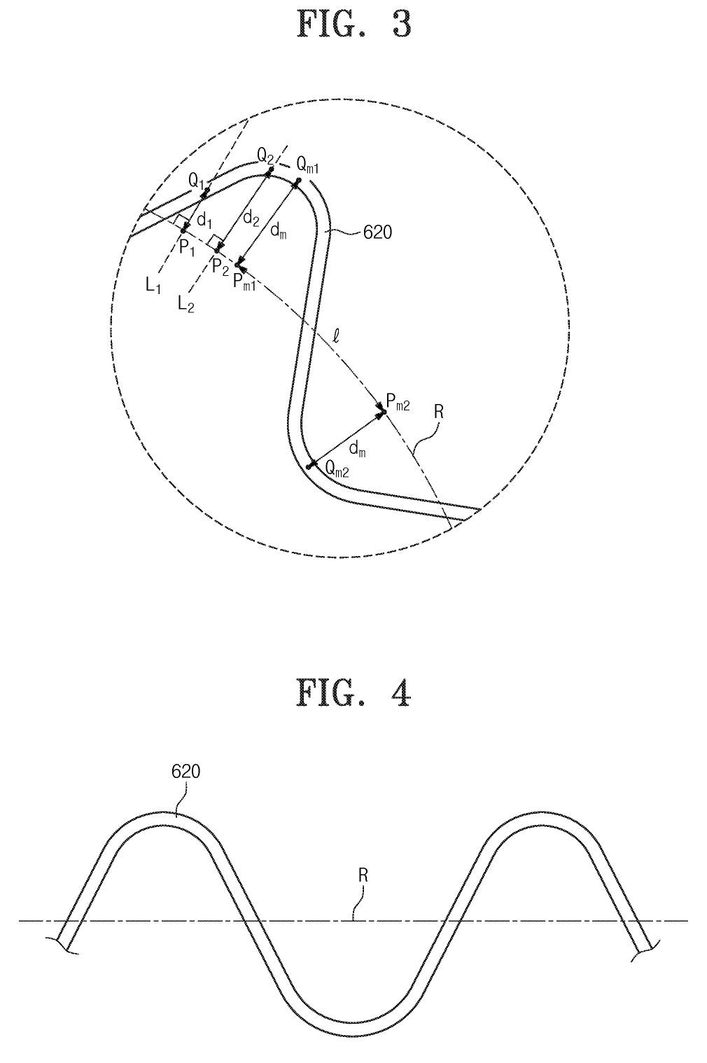

FIG. 2 is an exemplary plan view of an antenna 620 and FIG. 3 is an enlarged view of part A of FIG. 2.

Referring to FIG. 2, the antenna 620 may extend along imaginary baseline R having predetermined curvature. The antenna 620 may comprise a section where the distance between the baseline R and antenna changes depending on a position on the baseline R, the antenna is on a vertical line perpendicular to the baseline R.

Specifically referring to FIG. 3, the antenna 620 may include a first point P1 on the baseline R, a first vertical line L₁ which is perpendicular to the baseline R in the first point P₁, a first antenna point Q₁ on the first vertical line L₁, a second point P₂ on the baseline R, a second vertical line L₂ which is perpendicular to the baseline R in the second point P₂, and a second antenna point Q₂ on the second vertical line L₂. A distance d₁ between P₁ and Q₁ is different with a distance d₂ between P₂ and Q₂.

The distances d₁, d₂ between the baseline R and an intersection points Q₁, Q₂ between the antenna 620 and a vertical line perpendicular to the baseline R changes depending on positions P₁, P₂ on the baseline R.

The baseline R is an imaginary baseline and is adopted to show extension direction of the antenna 620. In the FIGS. 2 and 3, the baseline R may be a circle having fixed radius or a curve having predetermined curvature. However, the shape of the baseline is not limited herein.

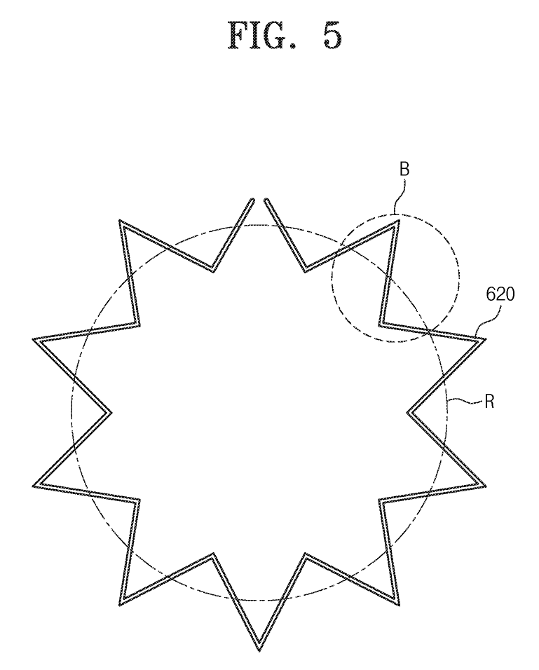

FIG. 4 is an exemplary plan view of an antenna 620 according to another example embodiment.

In an embodiment, the baseline R may be a curve where the curvature is positive number or a straight line where the curvature is 0.

As shown in FIG. 4, the antenna 620 may extend along a baseline R of a straight line. As described in prior, a distance between the baseline R and antenna changes depending on a position on the baseline R, the antenna is on a vertical line perpendicular to the baseline R.

In another embodiment, the baseline R may have a real number (0 or more) of curvature and the number of curvature may be changed depending on a position on the baseline R. For example, in the baseline R, a curvature may be constant with a first curvature value in a first section, a curvature may be changing from the first curvature value to a second curvature value in a second section, and a curvature may be constant with the second curvature value in a third section.

According to an embodiment, in the antenna 620 P₁ and P₂ on the baseline R may be independent variable of a periodic function, and d₁ and d₂ may be dependent variable of a periodic function, d₁, d₂ is distance between the baseline R and intersection points Q₁, Q₂. That is, the antenna 620 may have a periodic function form which extends along the baseline R.

In an embodiment, the antenna 620 may have a sine function form which extends along the baseline R, like FIGS. 2 to 4. In the antenna 620, P₁ and P₂ on the baseline R may be independent variable of a sine function, and d1 and d2 may be dependent variable of a sine function.

However, the shape of the antenna is not limited herein.

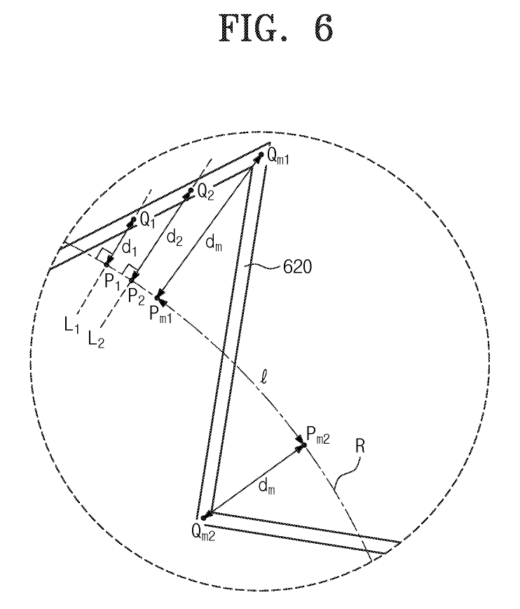

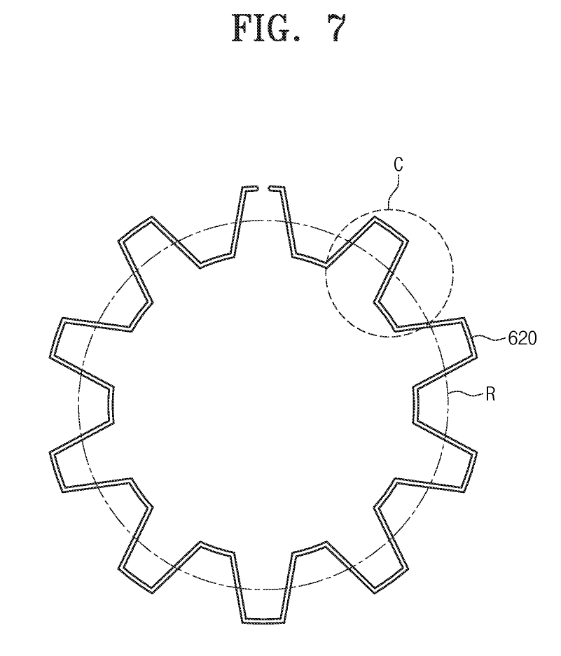

FIG. 5 is an exemplary plan view of an antenna 620 according to another example embodiment and FIG. 6 is an enlarged view of a part B of FIG. 5.

As shown in FIG. 5, the antenna 620 may extend along the baseline R as a triangle shape. In the antenna 620, P₁, P₂, and d₁, d₂ may be independent variable and dependent variable of a linear function in some section of the antenna 620, respectively.

According to an embodiment, in the antenna 620 a hypotenuse of a triangle area may be a curve instead of a straight line like FIGS. 5 and 6. In the antenna 620, P₁, P₂, and d₁, d₂ may be independent variable and dependent variable of a polynomial function in some section of the antenna 620, respectively.

According to an embodiment, a maximum value of a distance between the baseline and the intersection point on the antenna may be the same or smaller than a minimum value of a length between points on the baseline R having maximum distance.

For example, referring to FIGS. 3 and 6, maximum value dₘ of a distance between the baseline R and the intersection point may be smaller than minimum value 1 or may be the same. Minimum value 1 is a distance between Pₘ₁ and Pₘ₂ on the baseline R having the maximum distance of dₘ. In a periodic function which corresponds to a shape of the antenna 620, an amplitude of the periodic function may be smaller or the same with the period of the periodic function.

In an embodiment, the antenna may further comprise a section where the distance is constant.

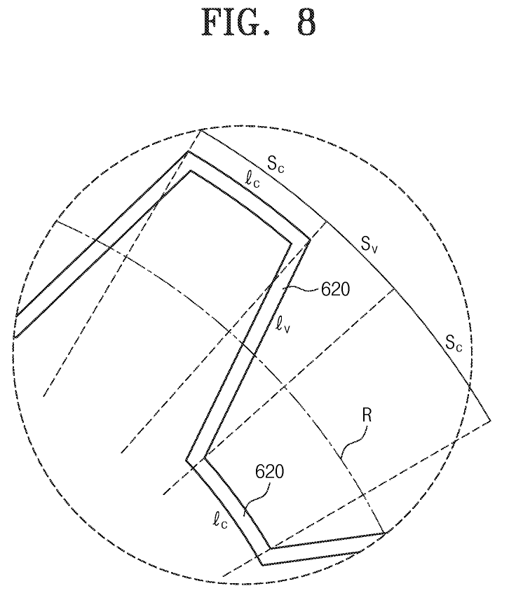

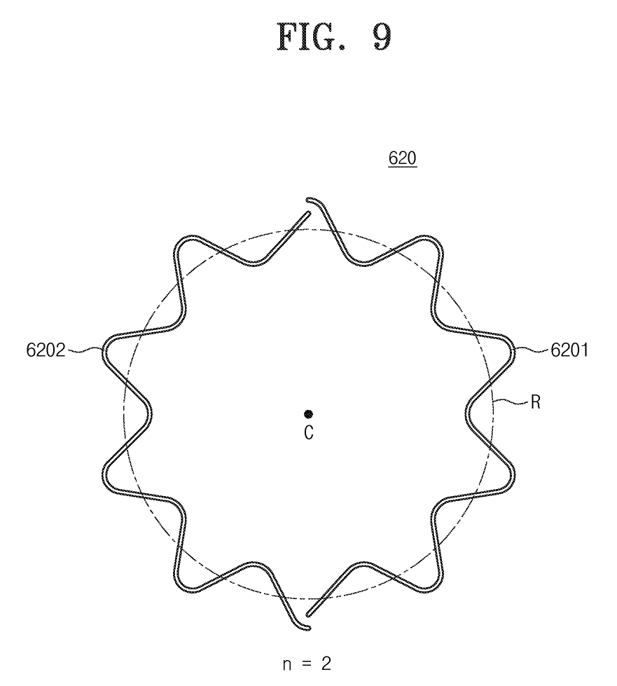

FIG. 7 is an exemplary plan view of an antenna 620 according to another example embodiment and FIG. 8 is an enlarged view of part C of FIG. 7.

As shown in FIGS. 7 and 8, the antenna 620 may comprise a section Sᵥ where the distance changes and a section S_{c} where the distance is constant.

In FIGS. 7 and 8, Sᵥ is where a shape of the antenna corresponds to the linear function and S_{c} is where dₘ is constant; the baseline R and antenna is parallel.

The antenna 620 may alternatively comprise Sᵥ and S_{c}.

In the antenna 620, a length lᵥ of the Sᵥ may be longer or the same with a length l_{c} of the S_{c}.

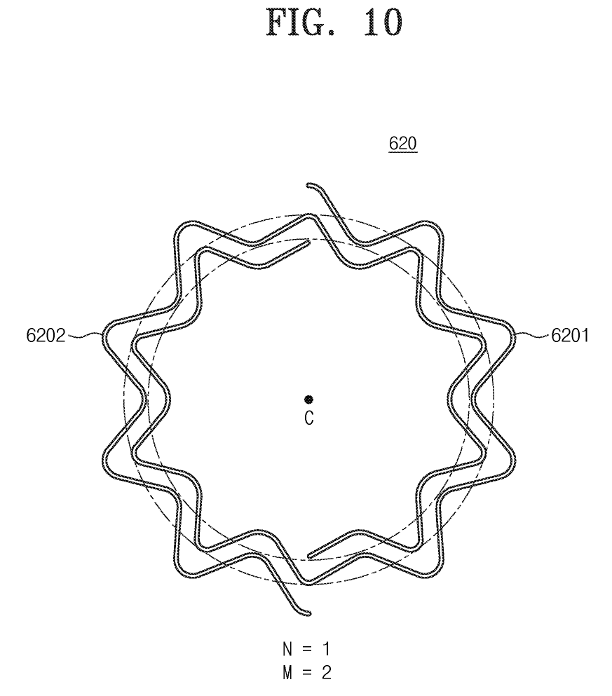

FIGS. 9 and 10 are exemplary plan views of an antenna 620 according to another example embodiment.

In another embodiment, the antenna 620 may comprise n number of winding wires extending over 360°/n of azimuth.n is a natural number.

In above embodiment, the azimuth is an angle between two straight lines which pass C on a plane (for example, parallel to upper surface of the chamber 100) where the antenna 620 exists.

According to above definition of the azimuth, a winding wire, which extends over 360° of azimuth, is extended by one rotation around point C. A winding wire, which extends over 180° of azimuth, is extended by half rotation around point C. A winding wire, which extends over 720° of azimuth, is extended by two rotations around point C.

In an embodiment of FIG. 9, n=2, and the antenna 620 comprises a first winding wire 6201 and a second winding wire 6202 which extends over 180° of azimuth. However, azimuth and a number (that is, n=2) of winding wires in the antenna 620 are not limited herein, and n may be 1 or a natural number more than 3.

Furthermore, n may be an even number respective to the antenna 620, and n number of winding wires may be arranged for the antenna 620 to be symmetrical. That is, the antenna 620 may comprise an odd number of winding wires, and the winding wires may be arranged around C for the antenna 620 to be symmetrical.

In another embodiment, the antenna 620 may comprise M number of winding wires extending over 360°×N of azimuth. In here, N is a real number bigger than 0, M is a natural number.

In an embodiment, when N is more than 1, each winding wires comprised in the antenna 620 may extend to rotate more than once around point C.

In an embodiment of FIG. 10, N=1=2, and the antenna 620 comprises a first winding wire 6201 and a second winding wire 6202 which extends over 360° of azimuth. However, azimuth and a number (that is, N=1, M=2) of winding wires in the antenna 620 are not limited herein.

The embodiments of the inventive concept provide an antenna having new structure and shape, and a substrate treating apparatus utilizing the same. In respective to a substrate treating apparatus using ICP way, it may improve distribution of an inductive electromagnetic field formed by the antenna, thereby reduce time of ignition and ionization, reduce a reflection power which returns to RF power by reflected from the antenna when igniting plasma, reduce substrate contamination and product damage from particle by reducing spike generated when igniting plasma, and enhance productivity of a substrate treating process.

Foregoing embodiments are examples of the present invention. Further, the above contents merely illustrate and describe preferred embodiments and embodiments may include various combinations, changes, and environments. That is, it will be appreciated by those skilled in the art that substitutions, modifications and changes may be made in these embodiments without departing from the principles and spirit, the scope of which is defined in the appended claims and their equivalents. Further, it is not intended that the scope of this application be limited to these specific embodiments or to their specific features or benefits. Rather, it is intended that the scope of this application be limited solely to the claims which now follow and to their equivalents.

What is claimed is:

1. An antenna extended along an imaginary baseline having predetermined curvature and comprising a section where the distance between the baseline and an intersection point between the antenna and a vertical line perpendicular to the baseline changes depending on a position on the baseline.

2. The antenna of claim 1, wherein the baseline comprises a straight line where a curvature is 0 or a curve where a curvature is a positive number.

3. The antenna of claim 1, wherein the baseline comprises a section where a curvature changes depending on a position on the baseline.

4. The antenna of claim 1, wherein a position on the baseline and the distance are independent variable and dependent variable of a periodic function, respectively.

5. The antenna of claim 4, wherein the position on the baseline and the distance are independent variable and dependent variable of a sine function, respectively.

6. The antenna of claim 4, wherein the position on the baseline and the distance are independent variable and dependent variable of a polynomial function or a linear function in some sections of the antenna, respectively.

7. The antenna of claim 4, wherein a maximum value of the distance is the same or smaller than a minimum value of a length between points on the baseline having maximum distance.

8. The antenna of claim 1, wherein the antenna further comprises a section where the distance is constant.

9. The antenna of claim 8, wherein the antenna alternatively comprises a section where the distance changes and a section where the distance is constant.

10. The antenna of claim 8, wherein a length of the section where the distance changes is longer or the same with the section where the distance is constant.

11. The antenna of claim 1, wherein the antenna comprises n number of winding wires extending over 360°/n of azimuth, n is a natural number.

12. The antenna of claim 11, wherein n is an even number and the n number of winding wires is arranged for the antenna to be symmetrical.

13. The antenna of claim 1, wherein the antenna comprises M number of winding wires extending over 360°×N of azimuth, N is a real number bigger than 0, and M is a natural number.

14. The antenna of claim 13, wherein M is an even number and the M number of winding wires is arranged for the antenna to be symmetrical.

15. A substrate treating apparatus comprising;
a chamber for providing a substrate treating space therein;
a substrate supporting assembly for supporting the substrate and placed within the chamber;
a gas supply unit for supplying a gas within the chamber; and
a plasma generating unit for making the gas into a plasma state,
wherein the plasma generating unit comprises:
a RF power for supplying RF signal; and
an antenna generating plasma from the gas supplied in the chamber by supplied with the RF signal, extended along an imaginary baseline having predetermined curvature, and comprises a section where the distance between the baseline point and the antenna point on a vertical line which is perpendicular to the base line changes depending on a position on the baseline.

16. The substrate treating apparatus of claim 15, wherein the baseline comprises a straight line where a curvature is 0 or a curve where a curvature is positive number.

17. The substrate treating apparatus of claim 15, wherein the baseline comprises a section where a curvature changes depending on a position on the baseline.

18. The substrate treating apparatus of claim 15, wherein a position on the baseline and the distance are independent variable and dependent variable of a periodic function, respectively.

19. The substrate treating apparatus of claim 18, wherein the position on the baseline and the distance are independent variable and dependent variable of a sine function, respectively.

20. The substrate treating apparatus of claim 18, wherein the position on the baseline and the distance are independent variable and dependent variable of a polynomial function or a linear function in some sections of the antenna, respectively.

21. The substrate treating apparatus of claim 18, wherein a maximum value of the distance is the same or smaller than a minimum value of a length between points on the baseline having the maximum value of the distance.

22. The substrate treating apparatus of claim 15, wherein the antenna further comprises a section where the distance is constant.

23. The substrate treating apparatus of claim 22, wherein the antenna alternatively comprises a section where the distance changes and a section where the distance is constant.

24. The substrate treating apparatus of claim 22, wherein a length of the section where the distance changes is longer or the same with the section where the distance is constant.

25. The substrate treating apparatus of claim 15, wherein the antenna comprises n number of winding wires extending over 360°/n of azimuth, n is a natural number.

26. The substrate treating apparatus of claim 15, wherein the antenna comprises M number of winding wires extending over 360°×N of azimuth, N is a real number bigger than 0, and M is a natural number.
